(19) United States
(12) Patent Application Publication
(10) Pub. No.: US 2009/0212863 A1
(43) Pub. Date: Aug. 27, 2009

(54) POWER AMPLIFIER

(76) Inventor: Yoshiteru ISHIMARU, Tenri-shi (JP)

Correspondence Address: BIRCH STEWART KOLASCH & BIRCH, PO BOX 747, FALLS CHURCH, VA, 22040-0747, US

(21) Appl. No.: 12/370,629

(22) Filed: Feb. 13, 2009

(30) Foreign Application Priority Data
Feb. 21, 2008 (JP) 2008-039735

(51) Int. Cl. H03F 3/45

(52) U.S. Cl. 330/253

(57) ABSTRACT

In the power amplifier of the invention, at a start of power amplification by an amplifier transistor 103 serving as an amplification section, a speedup circuit 122 transiently increases a bias which is fed to the amplifier transistor 103 via a bias power source section composed of a bias circuit 111 and a power source circuit 112. As a result, the power amplification factor of the amplifier transistor 103 is transiently increased at the start of power amplification by the amplifier transistor 103. Thus, the time elapsing until temperature variations due to heat generation of the amplifier transistor 103 come to an equilibrium on the whole circuit is shortened, with a result of reduced distortion of the amplification signal such as a modulated-wave signal. Accordingly, in the invention, it becomes possible to suppress distortion increases of an amplification signal due to heat generation at the start time without using any temperature sensing element.

### TECHNICAL FIELD

The present invention relates to power amplifiers and, for example, to a high-frequency power amplifier to be used in radio communication devices or the like.

### BACKGROUND ART

Conventionally, a power amplifier including a bipolar transistor is used as an amplifier for amplifying a signal or the like. Among others, a system that requires linear amplification such as a system using OFDM (Orthogonal Frequency Division Multiplex) modulated waves or the like has such a circuit design for linearization that the system runs on a linear amplification range of enough smaller outputs than a maximum output of the power amplifier so that the modulated-wave signal is not distorted in the power amplifier.

It should be noted here that the linear amplification mentioned above means that even with input signal power changed, the output signal power is amplified at a constant ratio for output while the phase keeps unchanged. In some communication systems, slight changes of amplification gain as small as 0.2 to 0.3 dB may matter.

As another aspect of the linear amplification, there are some cases in which variations in amplification ratio or phase on the order of several tens to several hundreds of us caused by relatively slow temperature increases due to heat generation as an example do matter. As a circuit for correcting effects of such heat generation by the power amplifier's own, there has been shown, in U.S. Pat. No. 4,924,194 (see FIG. 1), a circuit in which heat generation of an amplifier transistor is detected by a temperature sensing element (PIN diode) thermally coupled to the amplifier transistor and the detection result is reflected on a bias voltage of the amplifier transistor.

In this method using a temperature sensing element, there is a need for placing the temperature sensing element and the amplifier transistor close to each other to make the temperature sensing element thermally coupled to the amplifier transistor. Of course, an amplifier circuit for correcting effects of heat generation is a circuit for amplifying relatively large power. In this case, mutual close placement of the temperature sensing element and the amplifier transistor may cause an amplification signal to leak to the temperature sensing element, with a possibility of causing unexpected malfunction. For instance, in the case of the above example, when part of the amplification signal has leaked to the PIN diode, bias conditions may be changed by the rectification of the PIN diode. Otherwise, closeness of the pass channel of the amplification signal and the channel bound for the temperature sensing element may cause signal leakage to occur between the two channels, resulting in occurrence of similar malfunction.

### SUMMARY OF INVENTION

Technical Problem

Accordingly, an object of the present invention is to provide a power amplifier which is capable of suppressing distortion increases of an amplification signal due to heat generation upon start-up without using any temperature sensing element.

Solution to Problem

In order to achieve the above object, there is provided a power amplifier comprising:

an amplification section having a first transistor for performing power amplification;

a bias power source section having a second transistor for feeding a bias to the first transistor; and

a speedup circuit for transiently increasing the bias fed to the first transistor by bias power source section at a start of the power amplification.

According to the power amplifier of this invention, at a start of power amplification by the first transistor of the amplification section, the speedup circuit transiently (temporarily) increases the bias fed to the first transistor by the bias power source section, so that the power amplification factor of the first transistor is transiently increased at the start of power amplification. Thus, the time elapsing until temperature variations due to heat generation of the first transistor (amplifier transistor) that performs the power amplification come to an equilibrium on the whole circuit is shortened, with a result of reduced distortion of the amplification signal (e.g., modulated-wave signal).

In one embodiment of the invention, the second transistor has its emitter connected to a base of the first transistor via a resistance element, and

the bias power source section comprises:

a third transistor whose collector is connected to a base of the second transistor and whose emitter is connected to the ground;

a fourth transistor whose base is connected to the collector of the third transistor and whose emitter is connected to a base of the third transistor; and

a resistance element connected between the emitter of the fourth transistor and the ground,

the collectors of the second, third and fourth transistors being connected a control voltage source for controlling turn-on and -off of the power amplification, and wherein

the speedup circuit

is connected between a connecting point at which the base of the third transistor and the emitter of the fourth transistor are connected to each other and the control voltage source, and operates to, at a rise time of a control voltage of the control voltage source, transiently lower a base voltage of the third transistor to increase a current following into the base of the second transistor, whereby a current following into the base of the first transistor is increased so that a power amplification factor of the first transistor is increased.

According to the power amplifier of this embodiment, at a rise time of the control voltage of the control voltage source, the speedup circuit transiently lowers the base voltage of the third transistor to increase the current following into the base of the second transistor. As a result, at the rise time, the current following into the base of the first transistor is transiently increased, so that the power amplification factor of the first transistor is increased. Thus, the time elapsing until temperature variations due to heat generation of the first transistor serving as an amplifier transistor come to an equilibrium on the whole circuit is shortened, with a result of reduced distortion of the amplification signal (e.g., modulated wave signal).

That is, heat generation of transistors becomes larger in a transistor for signal amplification involving larger current consumption (first transistor), and smaller in a transistor for bias supply (second transistor). Then, in stages before the temperature's reach to the equilibrium, the temperature is higher at around the signal-amplification transistor and lower increasingly with increasing distance from the signal-amplification transistor, where these temperature differences cause the current value to vary, forming a cause of distortion of the modulated-wave signal. Therefore, turn-on behavior of the control voltage source in the amplifier depends on the layout of the amplifier, particularly on the placement of transistors, and amplifiers of the same layout result in the same characteristics as to turn-on and -off transient variations of the amplifiers.

Accordingly, in this invention, at the start of power amplification, i.e., immediately after the control voltage source that controls turn-on and -off of the power amplification is turned on so that the bias voltage is applied from the control voltage source to the first transistor via the bias power source section, the current following into the base of the first transistor is transiently increased by the speedup circuit. As a result of this, variations in the operating current due to heat generation of the power amplifier or the like can be canceled, by which variations in amplification factor can be suppressed, and improvement of the linearity can be achieved. That is, without use of any temperature sensing element, since the speedup circuit enabled to adjust the transient response of the operating current is connected to the bias power source section, distortion increases of the amplification signal (modulated-wave signal) due to heat generation can be suppressed.

By those effects, a power amplifier that transmits a larger radio signal with a smaller operating current can be obtained, so that such effects as reduction of power consumption, extension of operating time and elongation of communication distances of the radio communication device can be obtained.

In one embodiment of the invention, the speedup circuit has:

a fifth transistor whose collector is connected to the emitter of the fourth transistor and whose emitter is grounded via a resistance element;

a sixth transistor whose emitter is connected to a base of the fifth transistor and whose collector is connected to the control voltage source;

a capacitance element connected between a base of the sixth transistor and the control voltage source; and

a diode connected between the base of the sixth transistor and the control voltage source.

According to the power amplifier of this embodiment, by electric charge flowing into the capacitance element at a rise time of the control voltage of the control voltage source (upon turn-on of the amplifier), a current transiently (temporarily) flows into the collector of the fifth transistor, causing the voltage value of the collector to lower. As a result, due to a change of the bias point of the third transistor, the voltage of the connecting terminal at which the collector of the third transistor is connected to the base of the second transistor is temporarily increased. Thus, the current fed to the first transistor by the second transistor is transiently increased at the rise time. Therefore, the power amplification factor of the first transistor is transiently increased at the rise time, so that the time elapsing until temperature variations due to heat generation of the first transistor come to an equilibrium on the whole circuit is shortened, with a result of reduced distortion of the amplification signal (e.g., modulated wave signal).

In one embodiment of the invention, a capacitance value of the capacitance element of the speedup circuit is adjusted so as to cancel transient variations of gain due to temperature variations at a start of the power amplification.

According to the power amplifier of this embodiment, deterioration of the linearity due to variations of amplification gain can be canceled so that the value of dynamic EVM (error vector magnitude) can be improved.

In one embodiment of the invention, the capacitance value of the capacitance element of the speedup circuit is changeable.

According to the power amplifier of this embodiment, by changing the capacitance value of the capacitance element, it becomes possible for the speedup circuit to adjust the time duration during which the bias fed to the first transistor is kept increased at the start-up of amplification operation.

### ADVANTAGEOUS EFFECTS OF INVENTION

According to the power amplifier of the present invention, at a start of power amplification by the first transistor of the amplification section, the speedup circuit transiently increases the bias fed to the first transistor by the bias power source section, by which the power amplification factor of the first transistor is transiently increased at the start of the power amplification. Thus, the time elapsing until temperature variations due to heat generation of the first transistor (amplifier transistor) that performs the power amplification come to an equilibrium on the whole circuit is shortened, with a result of reduced distortion of the amplification signal (e.g., modulated wave signal).

### BRIEF DESCRIPTION OF DRAWINGS

FIG. 1 is a circuit diagram showing an embodiment of the power amplifier according to the present invention;

FIG. 2 is a characteristic view showing an example of transient response in a comparative example of the embodiment; and

FIG. 3 is a characteristic view showing an example of transient response of the embodiment.

### DESCRIPTION OF EMBODIMENTS

Hereinbelow, the present invention will be described in detail by way of embodiments thereof illustrated in the accompanying drawings.

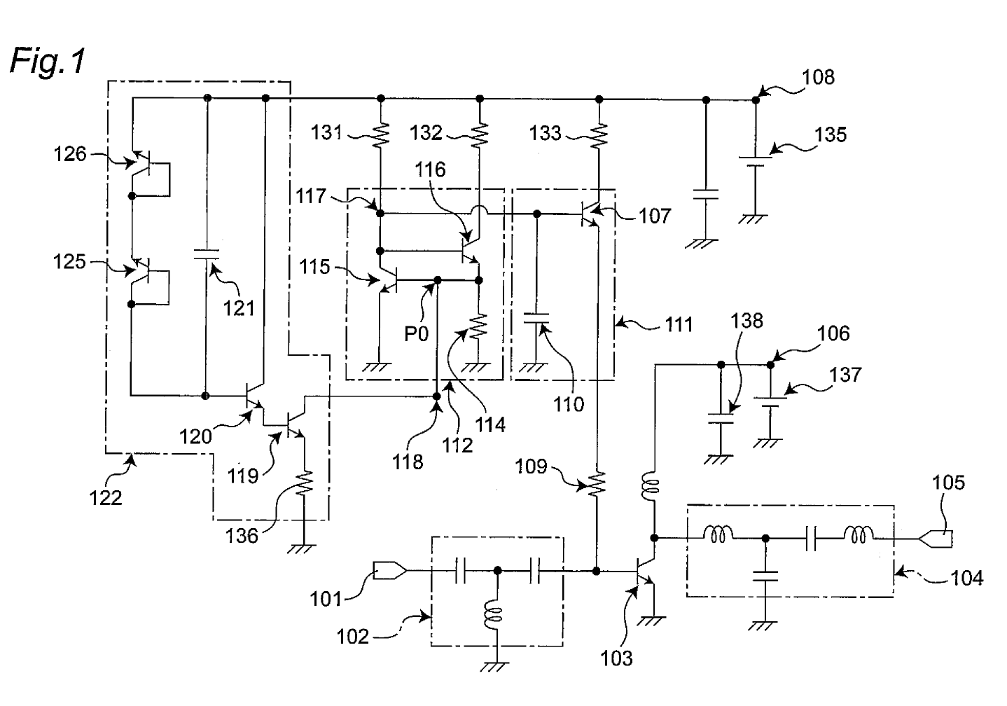

FIG. 1 is a circuit diagram showing a circuit construction in an embodiment of the power amplifier of the invention.

In this power amplifier, a high-frequency signal as an input signal inputted from an input signal terminal 101, passing through an input matching circuit 102, is amplified by an amplifier transistor 103 serving as a first transistor, and then, after passing through an output matching circuit 104, outputted from an output signal terminal 105. In FIG. 1, reference sign 106 denotes a collector bias terminal of the amplifier transistor 103. Between the collector bias terminal 106 and the ground are connected a DC power source 137 and a capacitance element 138. The amplifier transistor 103 forms an amplification section.

Also, a bias transistor 107 as a second transistor is a transistor that supplies a base bias current to a base terminal of the amplifier transistor 103. An emitter of the bias transistor 107 is connected to a base terminal of the amplifier transistor 103 via a resistance element 109. The resistance element 109 is a ballast (stabilization) resistor which is inserted in a base bias channel to prevent thermal runaway of the amplifier transistor 103.

The bias transistor 107 has its collector connected to a bias terminal 108 via a resistance element 133. The bias terminal 108 is connected to a control voltage source 135.

A bias circuit 111 composed of the bias transistor 107 and a capacitance element 110 connected to a base terminal of the bias transistor 107 has a function of increasing the base bias current in response to an increase in signal strength of the input signal, and functions to keep the amplification ratio of an output signal as well as its phase rotation after amplification constant even when the signal strength of the input signal has changed.

A power source circuit 112 is connected to the base terminal of the bias transistor 107 of the bias circuit 111. The bias circuit 111 and the power source circuit 112 constitute a bias power source section.

The power source circuit 112 feeds generally a sum of a “base-emitter voltage” of the amplifier transistor 103 and a “base-emitter voltage” of the bias transistor 107 to the base terminal of the bias transistor 107. That is, the power source circuit 112 feeds a voltage double the base-emitter voltage (hereinafter, referred to as VBE) of a transistor used in the power source circuit 112 to the base terminal of the bias transistor 107. It is noted that voltage drops of the ballast resistor 109 are neglected in this case.

In this embodiment, as shown in FIG. 1, the power source circuit 112 has a third transistor 115, a fourth transistor 116, and a resistance element 114. The third transistor 115 has its collector connected to the base of the bias transistor 107 and its emitter connected to the ground. Also, a base of the third transistor 115 is connected to an emitter of the fourth transistor 116. The collector of the third transistor 115 is connected to the bias terminal 108 via a resistance element 131. Meanwhile, the fourth transistor 116 has its emitter connected to the ground via the resistance element 114 and its collector connected to the bias terminal 108 via a resistance element 132.

A connecting point P0 between the base of the third transistor 115 and the emitter of the fourth transistor 116 in the power source circuit 112 is connected to an output terminal 118 of a speedup circuit 122.

The speedup circuit 122 has a fifth transistor 119 whose collector is connected to the output terminal 118, and a sixth transistor 120 whose emitter is connected to a base of the fifth transistor 119. The emitter of the fifth transistor 119 is connected to the ground via a resistance element 136.

The speedup circuit 122 also has a capacitance element 121 which is connected between a base of the sixth transistor 120 and the bias terminal 108, and two diodes 125, 126 which are connected in series between the base of the sixth transistor 120 and the bias terminal 108.

In the speedup circuit 122, with electric charge flowing into the capacitance element 121 at a rise time of the control voltage of the control voltage source 135 (at turn-on of the amplifier), a current transiently (temporarily) flows from the output terminal 118 into the fifth transistor 119, causing the voltage value of the output terminal 118 to lower. As a result, due to a change of the bias point of the third transistor 115, the voltage of a connecting terminal 117, which connects the collector of the third transistor 115 to the base of the bias transistor 107, transiently increases. Thus, at the rise time, the current fed to the amplifier transistor 103 by the bias transistor 107 transiently increases. Therefore, at the rise time, the power amplification factor of the amplifier transistor 103 transiently increases, so that the time elapsing until temperature variations due to heat generation of the amplifier transistor 103 come to an equilibrium on the whole circuit is shortened, with a result of reduced distortion of the amplification signal (e.g., modulated wave signal).

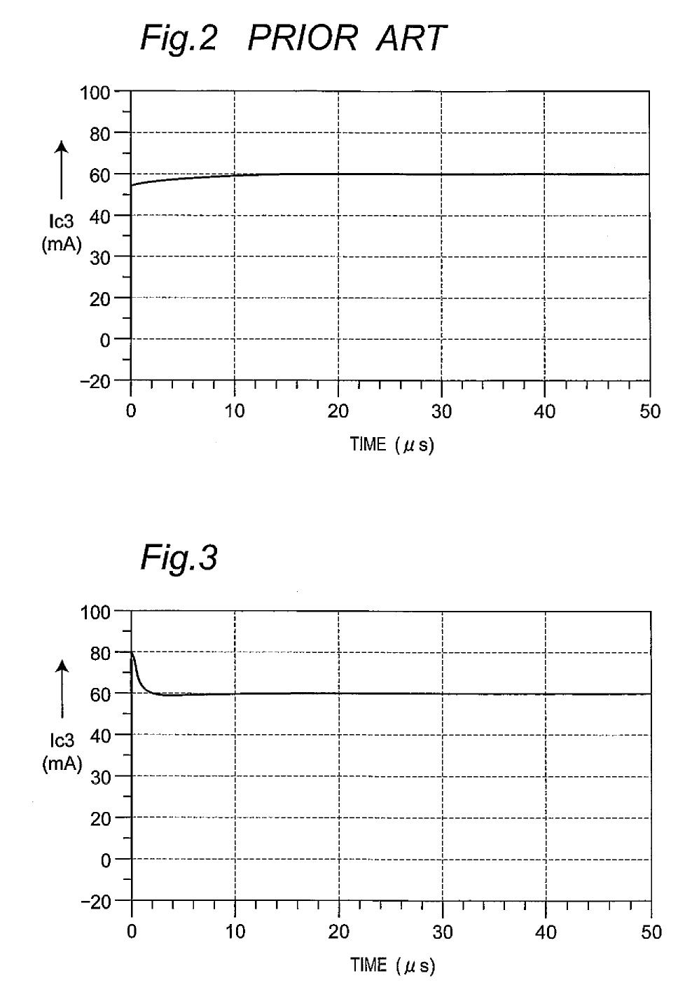

FIG. 2 shows an example of transient response of an operating current (collector current Ic3) of the amplifier transistor 103 in a comparative example in which the speedup circuit 122 is removed in the circuit of FIG. 1. In this comparative example having no speedup circuit, due to the fact that a temperature increasing rate of the bias transistor 107 is slower than that of the amplifier transistor 103, the value of the current fed from the bias circuit 111 to the amplifier transistor 103 continues to vary, the variations in current value making a cause of signal distortion.

Next, FIG. 3 shows an example (simulation result) of transient response of the operating current (collector current Ic3) of the amplifier transistor 103 in the power amplifier of this embodiment. In this embodiment, the current to be fed from the bias transistor 107 to the amplifier transistor 103 is forcedly increased at turn-on of the amplifier, with the result that the value of the operating current Ic3 comes to a steady state in about ¼ the time of transient response of the comparative example of FIG. 2. Thus, occurrence of distortions of the amplification signal due to temperature variations in the amplifier circuit is suppressed, so that the linearity of the circuit in burst operation is improved. That is, gain variations due to collector current variations of the power amplifier using a bipolar transistor can be compensated.

In the power amplifier of this embodiment also, the capacitance value of the capacitance element 121 of the speedup circuit 122 is adjusted so as to cancel transient variations in gain due to the temperature variations at a start of power amplification. As a result of this, deterioration of the linearity due to variations of amplification gain can be canceled so that the value of dynamic EVM (error vector magnitude) can be improved.

In addition, the capacitance element 121 of the speedup circuit 122 may be a capacitance element whose capacitance value is changeable. In this case, changing the capacitance value of the capacitance element 121 makes it possible to adjust the time duration during which the bias fed to the amplifier transistor 103 at a start of amplification operation by the speedup circuit 122 via the bias power source section composed of the power source circuit 112 and the bias circuit 111 is kept increased.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### REFERENCE SIGNS LIST

101 input signal terminal

102 input matching circuit

103 amplifier transistor

104 output matching circuit

105 output signal terminal

106 collector bias terminal

107 bias transistor

108 bias terminal

109 ballast (stabilization) resistor

110 capacitance element

111 bias circuit

112 power source circuit

114 resistance element

115 third transistor

116 fourth transistor

117 connecting terminal

118 output terminal

119 fifth transistor

120 sixth transistor

121 capacitance element

122 speedup circuit

125, 126 diode

### CITATION LIST

Patent Literature

U.S. Pat. No. 4,924,194 (see FIG. 1)

1. A power amplifier comprising:
an amplification section having a first transistor for performing power amplification;
a bias power source section having a second transistor for feeding a bias to the first transistor; and
a speedup circuit for transiently increasing the bias fed to the first transistor by bias power source section at a start of the power amplification.

2. The power amplifier as claimed in claim 1, wherein
the second transistor has its emitter connected to a base of the first transistor via a resistance element, and
the bias power source section comprises:
a third transistor whose collector is connected to a base of the second transistor and whose emitter is connected to the ground;
a fourth transistor whose base is connected to the collector of the third transistor and whose emitter is connected to a base of the third transistor; and
a resistance element connected between the emitter of the fourth transistor and the ground,
the collectors of the second, third and fourth transistors being connected a control voltage source for controlling turn-on and -off of the power amplification, and wherein
the speedup circuit
is connected between a connecting point at which the base of the third transistor and the emitter of the fourth transistor are connected to each other and the control voltage source, and operates to, at a rise time of a control voltage of the control voltage source, transiently lower a base voltage of the third transistor to increase a current following into the base of the second transistor, whereby a current following into the base of the first transistor is increased so that a power amplification factor of the first transistor is increased.

3. The power amplifier as claimed in claim 2, wherein
the speedup circuit has:
a fifth transistor whose collector is connected to the emitter of the fourth transistor and whose emitter is grounded via a resistance element;
a sixth transistor whose emitter is connected to a base of the fifth transistor and whose collector is connected to the control voltage source;
a capacitance element connected between a base of the sixth transistor and the control voltage source; and
a diode connected between the base of the sixth transistor and the control voltage source.

4. The power amplifier as claimed in claim 3, wherein
a capacitance value of the capacitance element of the speedup circuit is adjusted so as to cancel transient variations of gain due to temperature variations at a start of the power amplification.

5. The power amplifier as claimed in claim 3, wherein
the capacitance value of the capacitance element of the speedup circuit is changeable.
